(19) United States
(12) Patent Application Publication
(10) Pub. No.: US 2025/0275058 A1
(43) Pub. Date: Aug. 28, 2025

(54) ARRANGEMENT HAVING A PRINTED CIRCUIT BOARD AND A POWER ELECTRONICS COMPONENT, AND METHOD OF PRODUCTION

(71) Applicants: Semikron Danfoss Elektronik GmbH & Co. KG, Nürnberg (DE); Semikron Danfoss GmbH, Flensburg (DE)

(72) Inventors: Stefan Behrendt, Eckernförde (DE); Heiko Braml, Wiesenttal (DE); Eike Hahn, Erlangen (DE); Matthias Hörteis, Lauf an der Pegnitz (DE)

(21) Appl. No.: 19/065,426

(22) Filed: Feb. 27, 2025

(30) Foreign Application Priority Data
Feb. 28, 2024 (DE) 102024105616.9

(51) Int. Cl. H05K 1/02; H05K 1/18; H05K 3/34

(52) U.S. Cl. CPC H05K 1/0296; H05K 1/181; H05K 3/341; H05K 2203/107

(57) ABSTRACT

What are presented are a method of production and an arrangement having a printed circuit board and a power electronics component, wherein the component has a second contact surface having a normal direction, wherein the printed circuit board has a first conductor track having a first contact surface which is flush with the second contact surface in normal direction and is connected thereto in a materially bonded and electrically conductive manner, wherein the first contact surface is assigned an opposite surface of the first conductor track which is disposed above it in normal direction and which is accessible, especially to a laser beam, from normal direction, especially in the course of a welding operation.

### CROSS-REFERENCE TO RELATED APPLICATION

This application claims foreign priority benefits under 35 U.S.C. § 119 to German Patent Application No. 102024105616.9 filed on Feb. 28, 2024, the content of which is hereby incorporated by reference in its entirety.

### TECHNICAL FIELD

The invention describes an arrangement having a printed circuit board and a power electronics component, especially a power electronics substrate, wherein the component has a second contact surface having a normal direction N, wherein the printed circuit board has a first conductor track having a first contact surface which is flush with the second contact surface in normal direction N and is connected thereto in a materially bonded and electrically conductive manner. The invention further describes a method of producing such an arrangement.

### BACKGROUND

DE 10 2022 117 625 B3 discloses an arrangement having a housing and an electrically conductive contact spring, wherein this contact spring has a first and a second orthogonal main plane in its specified spring direction, wherein it is designed to be symmetric with respect to the first main plane, x-z plane, and asymmetric with respect to the second main plane, x-y plane, and also with respect to a rotation through 180° about the specified spring direction, wherein the housing has a spring shaft for receiving the contact spring, and wherein this spring shaft likewise has a first and a second main plane which coincide with the respective main plane of the contact spring, and wherein the spring shaft is designed to be symmetric relative to both main planes. Likewise presented is a power semiconductor module comprising such an arrangement.

DE 10 2020 100 364 A1 discloses a power electronics assembly having a substrate, having a sleeve and having a contact pin, wherein the sleeve is disposed on a conductor track of the substrate and a bottom section of the sleeve is connected to the conductor track in a materially bonded and electrically conductive manner, wherein the contact pin is positioned by an inserted section in an inner recess of the sleeve and wherein an electrically conductive material-material weld bond formed by laser welding is formed between a pin connection section of the inserted section of the contact pin and an assigned sleeve connection section of the sleeve.

### SUMMARY

With knowledge of the prior art, it is an object of the invention to present a compact, easily establishable arrangement of a printed circuit board with a power electronics component, and to specify a method of producing said arrangement.

This object is achieved in accordance with the invention by an arrangement having a printed circuit board and a power electronics component, wherein the component has a second contact surface having a normal direction, wherein the printed circuit board has a first conductor track having a first contact surface which is flush with the second contact surface in normal direction and is connected thereto in a materially bonded and electrically conductive manner, wherein the first contact surface is assigned an opposite surface of the first conductor track which is disposed above it in normal direction and which is accessible, especially to a laser beam, from normal direction, especially in the course of a welding operation.

It may be advantageous here when the power electronics component takes the form of a power electronics substrate, and the second contact surface is disposed on a second conductor track of said substrate. What is meant in particular by a power electronics substrate is a substrate having a multitude of conductor tracks that are capable of carrying load currents with amperages in the region above 50 A and are disposed on an insulating main body. By way of example, these are conventional DCB or IMS substrates.

Alternatively, it may be advantageous when the power electronics component takes the form of a preferably exposed first semiconductor component, especially a first power semiconductor component, and the second contact surface is disposed on a contact surface of said first semiconductor component. Advantageously, said first semiconductor component is in turn disposed on a power electronics substrate.

It is fundamentally advantageous when the printed circuit board is rigid, by way of example made of a composite material composed of cured epoxy resin and glass fibre weave, or flexible, by way of example in the form of an alternating stack of electrically conductive and electrically insulating films.

It may be preferable when the printed circuit board, viewed in normal direction, is disposed alongside the power electronics component, especially if it is designed as a power electronics substrate, to an extent of more than 40%, preferably to an extent of more than 70% and especially preferably to an extent of more than 90%. It may also be preferable when the printed circuit board here covers a large area of the power electronics substrate and leaves a multitude of regions clear.

It may be advantageous when the second contact surface is disposed together with a third contact surface on the second conductor track, and said third contact surface has a direct electrically conductive connection to a connecting device which itself preferably takes the form of a wire bond or of a film stack composed of two electrically conductive films and one electrically insulating film in between. A direct electrically conductive connection shall especially be understood to mean a bond without further connecting bodies. By way of example, direct bonds take the form of solder, sinter and weld bonds. It may be particularly advantageous here when the connecting device also has a direct electrically conductive connection to a fourth contact surface disposed on a third conductor track or a second semiconductor component.

It is particularly preferable when the opposite surface is fully or partly surrounded by an insulation layer of the printed circuit board. It may be further preferable here when a section of the insulation layer is electrically conductive, and the opposite surface is electrically connected to a further conductor track of the printed circuit board.

It is particularly advantageous when the first contact surface is disposed on a tab that protrudes laterally from the printed circuit board orthogonally to normal direction.

The above-specified object is additionally achieved in accordance with the invention by a method of electrically conductive material-material connection of a first contact surface of a printed circuit board to a second contact surface of a power electronics component, wherein the second contact surface has a normal direction, wherein the first contact surface is flush with the second contact surface in normal direction and wherein the first contact surface is assigned an opposite surface in normal direction which is accessible to a laser beam, wherein the bond is formed by the action of a laser beam on the opposite surface until the bond has formed.

It may be advantageous here when a bonding medium is disposed between the first and second contact surfaces before the laser beam acts on the opposite surface.

It may in principle be advantageous when the bonding medium is selected from: first suspension of a liquid medium and metal particles; second suspension of a pasty medium and metal particles; adhesive incorporating metal particles; solder material, preferably in platelet form. It may also be advantageous here when the metal particles take the form of silver or copper particles, or have a proportion of more than 50% by weight of these substances.

Of course, unless ruled out explicitly or per se or contradictory to the concept of the invention, the features mentioned in the singular in each case, in particular the different contact surfaces, may be replicated in the arrangement according to the invention.

It will be apparent that the various configurations of the invention are applicable no matter whether they are disclosed in the context of the description of the arrangement or of the method. In particular, the features mentioned and explained above and hereinafter are usable not only in the combinations indicated, but also in other combinations or by themselves, without departing from the scope of the present invention.

### BRIEF DESCRIPTION OF THE DRAWINGS

Further elucidations of the invention, advantageous details and features will be apparent from the description of the working examples of the invention illustrated schematically in FIGS. 1 to 7 that follows, or from respective parts thereof.

FIGS. 1 and 2 show two different views of a first configuration of an arrangement according to the invention.

FIGS. 3 and 4 show two different views of a second configuration of an arrangement according to the invention.

FIGS. 5 and 6 show top views of further configurations of an arrangement according to the invention.

FIG. 7 shows a lateral view of a further configuration of an arrangement according to the invention.

### DETAILED DESCRIPTION

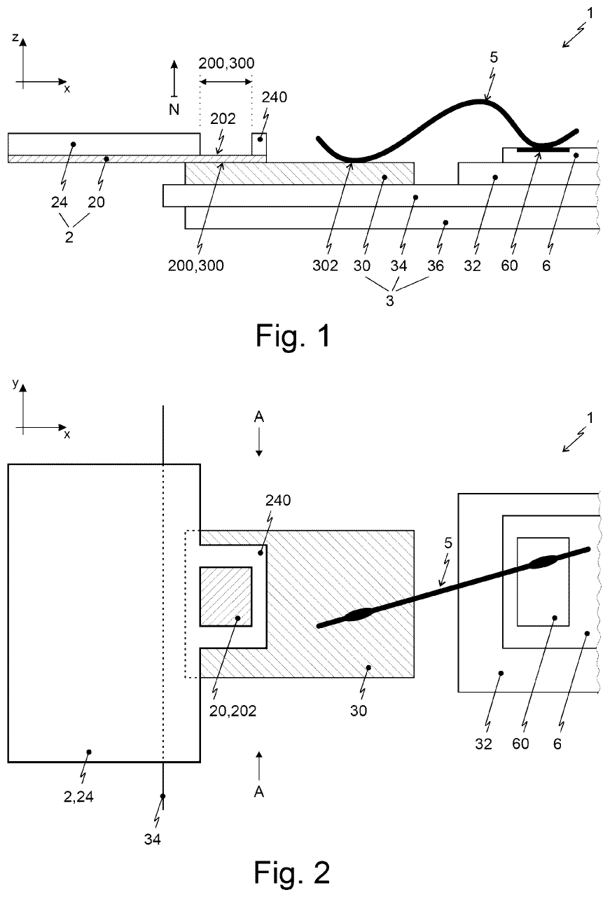

FIGS. 1 and 2 show two different views of a first configuration of an arrangement 1 according to the invention. FIG. 2 shows the top view here, and FIG. 1 a section along the line A-A through this top view. What is shown is a power electronics component 3, in the form of a power electronics substrate which is customary in the art here. This substrate has an insulant body 34, in the form of a ceramic plate here. Disposed on the first main surface, the upper surface here, of the ceramic plate is a first metallic layer, which is divided into sections, as a result of which these sections form conductor tracks 30, 34 of the substrate 3. A second metallic layer 36 is disposed on the second main surface, the lower surface here, of the ceramic plate.

A second conductor track 30 of the substrate has, on its surface remote from the ceramic 34, a section having a second contact surface 300 that defines a normal direction N. A second power semiconductor component 6 is disposed on a third conductor track 32 of the substrate and is connected in an electrically conductive manner to said third conductor track 32. A connection surface 60 is disposed on a side of the second power semiconductor component 6 remote from the third conductor track 32. This connection surface 60 is connected to the second conductor track 30 in an electrically conductive manner. Purely by way of example, this bond takes the form of a wire bond.

Also shown is a printed circuit board 2, purely by way of example in rigid form, made from standard FR4 material. This printed circuit board 2 has a first conductor track 20 having a first contact surface 200 which faces the second contact surface 300 and is flush with the second contact surface 300 in normal direction N. According to the invention, this first contact surface 200 is connected in a materially bonded and hence directly electrically conductive manner to the second contact surface 300. The first conductor track 20 has an opposite surface 202 which is above it when viewed in normal direction N and is thus in a flush arrangement with the first contact surface 200. The first contact surface 200 and the opposite surface 202 are not necessarily of the same dimensions.

The printed circuit board 2 is formed such that the opposite surface 202 of the first conductor track 20 is accessible from normal direction N. This means that no part of the printed circuit board 2 is disposed above the opposite surface 202 in normal direction N. This opposite surface 202 is thus accessible from normal direction N, especially for formation of the material-material bond of the first contact surface 200 to the second contact surface 300. Purely by way of example, the opposite surface 202 is accessible here to a laser beam which acts on the opposite surface 202 in a laser welding operation.

The material-material bond is formed by a laser-induced method in which a laser beam acts on the opposite surface 202 while the first contact surface 200 is in direct or indirect contact with the second contact surface 300.

In the case of direct contact, there is no bonding medium, nor any other material, disposed between the first and second contact surfaces 200, 300. The laser exposure then results in a weld bond of the first conductor track 20 to the second conductor track 30 in the regions of the contact surfaces 200, 300.

In the case of indirect contact, a bonding medium, purely by way of example a layer of a particle-containing suspension, is disposed between the first and second contact surfaces 200, 300. The solvent of the suspension is evaporated by the action of the laser, and the metal particles, purely by way of example copper particles, are bonded to one another and to the contact surfaces 200, 300. A preferred alternative bonding medium is a solder, in which case the material-material bond takes the form of a laser-induced solder bond.

Particularly for mechanical stabilization of that section of the first conductor track 20 having the first contact surface 200 and the opposite surface 202, which takes the form of a tab here, the opposite surface 202 is fully or partly surrounded by an insulation layer 240 of the printed circuit board 2. This insulation layer 240 consists, in one-piece form, of the insulation material 24 of the printed circuit board 2.

Although not shown, it is advantageously possible for a section, especially the inner edge of the insulation layer 240, to be electrically conductive and hence to electrically connect the opposite surface 202 to a further conductor track of the printed circuit board 2. This further conductor track is advantageously disposed above the opposing surface 202 in normal direction N, but offset laterally.

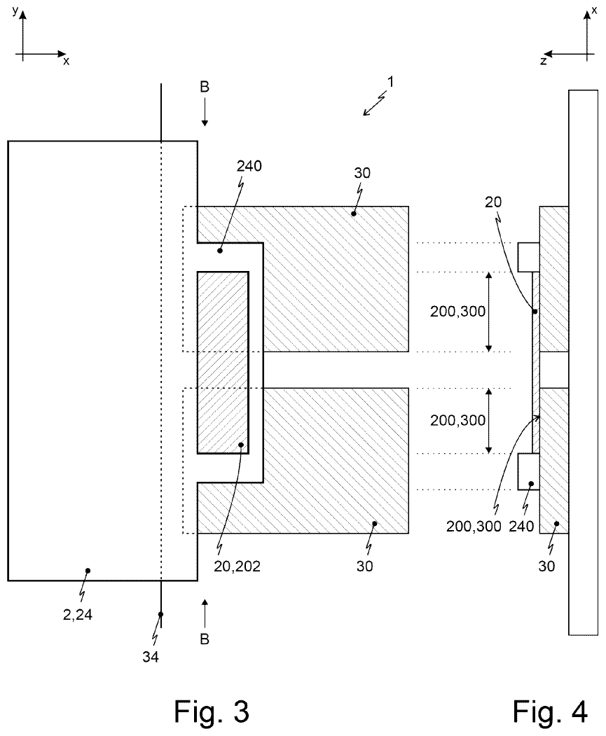

FIGS. 3 and 4 show two different views of a second configuration of an arrangement according to the invention. FIG. 3 here shows the top view, and FIG. 4 a section along the line B-B. This configuration differs from that according to FIGS. 1 and 2 in that the substrate here has two second conductor tracks 30, each of which has a second contact surface 300. The respective second contact surface 300 is connected in a materially bonded and hence directly electrically conductive manner in each case to a corresponding first contact surface 200 of a first conductor track 20 of the printed circuit board 2.

The two first contact surfaces 200 are disposed on the respective sections of a common first conductor track 20 of the printed circuit board 2. This configuration and arrangement of the first conductor track 20 allows indirect electrical connection between the two second conductor tracks 30 of the substrate by means thereof.

The first contact surfaces 200 of the first conductor track 20 are in turn disposed on a tab-like section of this first conductor track 20, where the tab-like section protrudes from the printed circuit board 2 orthogonally to normal direction N.

This tab-like section, for stabilization thereof, is fully surrounded by an insulation layer 240 of the printed circuit board 2, where this insulation layer 240 leaves the respective opposite surfaces 202 clear, in order that they are accessible from normal direction N.

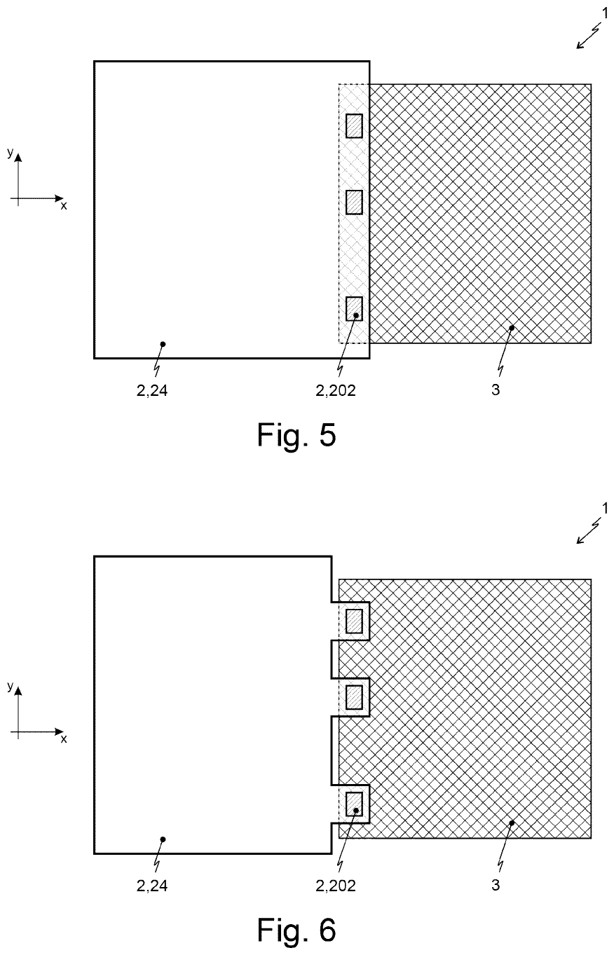

FIGS. 5 and 6 show top views of further configurations of an arrangement according to the invention. In the configuration according to FIG. 5, the printed circuit board 2 does not have any tab-like sections. Instead, the opposite surfaces 202 here (cf. FIGS. 1 to 4) are left clear, while the printed circuit board 2 has a rectangular outline and, viewed in normal direction N, is disposed alongside the power electronics component 3 to an extent of 90%, which here in turn takes the form of a substrate as described for FIG. 1.

In the configuration according to FIG. 6, the printed circuit board 2 has a multitude of tab-like sections which are basically of the form according to FIGS. 1 and 2. By virtue of this configuration, viewed in normal direction N, the printed circuit board 2 is disposed alongside the power electronics component 3, which here in turn takes the form of a substrate as described for FIG. 1, to an extent of more than 90%.

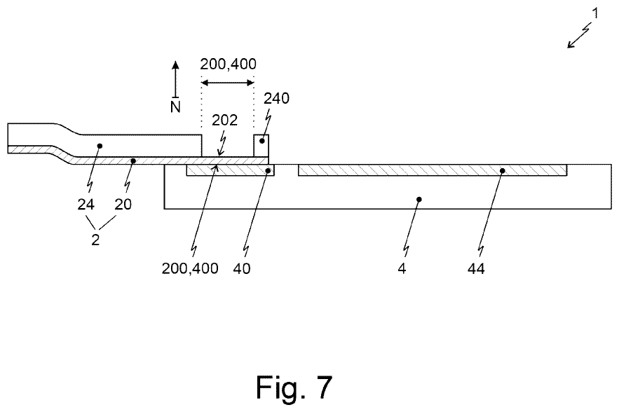

FIG. 7 shows a lateral view of a further configuration of an arrangement according to the invention. In this configuration, the power electronics component 4 takes the form of an exposed first semiconductor component, especially a first power semiconductor component. A contact surface 40 on the top side of this first semiconductor component, viewed in normal direction N, forms the second contact surface 400 here.

In addition, this configuration differs from that described so far according to FIGS. 1 to 6 in that the printed circuit board 2 is flexible.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. An arrangement having a printed circuit board and a power electronics component, wherein the component has a second contact surface having a normal direction (N), wherein the printed circuit board 2 has a first conductor track having a first contact surface which is flush with the second contact surface in normal direction (N) and is connected thereto in a materially bonded and electrically conductive manner, wherein the first contact surface is assigned an opposite surface of the first conductor track 20 which is disposed above it in normal direction (N) and which is accessible, especially to a laser beam, from normal direction (N), especially in the course of a welding operation.

2. The arrangement according to claim 1, wherein the power electronics component takes the form of a power electronics substrate, and the second contact surface is disposed on a second conductor track of said substrate.

3. The arrangement according to claim 1, wherein the power electronics component takes the form of a preferably exposed first semiconductor component, especially a first power semiconductor component, and the second contact surface is disposed on a contact surface of said first semiconductor component.

4. The arrangement according to claim 1, wherein
the printed circuit board is rigid or flexible.

5. The arrangement according to claim 1, wherein
the printed circuit board, viewed in normal direction (N), is arranged alongside the power electronics component to an extent of more than 40%, preferably to an extent of more than 70% and especially preferably to an extent of more than 90%.

6. The arrangement according to claim 1, wherein
the second contact surface is disposed together with a third contact surface on the second conductor track, and said third contact surface has a direct electrically conductive connection to a connecting device which itself preferably takes the form of a wire bond or of a film stack composed of two electrically conductive films and one electrically insulating film in between.

7. The arrangement according to claim 6, wherein the connecting device also has a direct electrically conductive connection to a fourth contact surface disposed on a third conductor track or a second semiconductor component.

8. The arrangement according to claim 1, wherein
the opposite surface is fully or partly surrounded by an insulation layer of the printed circuit board.

9. The arrangement according to claim 8, wherein a section of the insulation layer is electrically conductive and electrically connects the opposite surface to a further conductor track of the printed circuit board.

10. The arrangement according to claim 1, wherein
the first contact surface is disposed on a tab that protrudes laterally from the printed circuit board orthogonally to normal direction (N).

11. A method of electrically conductive material-material connection of a first contact surface of a printed circuit board to a second contact surface of a power electronics component, wherein the second contact surface has a normal direction (N), wherein the first contact surface is flush with the second contact surface in normal direction (N) and wherein the first contact surface is assigned an opposite surface in normal direction (N) which is accessible to a laser beam, wherein the bond is formed by the action of a laser beam on the opposite surface until the bond has formed.

12. The method according to claim 11, wherein a bonding medium is disposed between the first and second contact surfaces before the laser beam acts on the opposite surface.

13. The method according to claim 12, wherein the bonding medium is selected from
first suspension of a liquid medium and metal particles;
second suspension of a pasty medium and metal particles;
adhesive incorporating metal particles;
solder material, preferably in platelet form.

14. The method according to claim 13, wherein the metal particles take the form of silver or copper particles.
